(19) United States
(12) Patent Application Publication
(10) Pub. No.: US 2019/0293589 A1
(43) Pub. Date: Sep. 26, 2019

(54) DETECTION DEVICE, MEASUREMENT APPARATUS, AND MANUFACTURING METHOD FOR DETECTION DEVICE

(71) Applicant: FUJITSU LIMITED, Kawasaki-shi (JP)

(72) Inventors: Satoru Momose, Atsugi (JP); Michio USHIGOME, Atsugi (JP); Osamu Tsuboi, Kawasaki (JP)

(73) Assignee: FUJITSU LIMITED, Kawasaki-shi (JP)

(21) Appl. No.: 16/285,279

(22) Filed: Feb. 26, 2019

(30) Foreign Application Priority Data
Mar. 20, 2018 (JP) 2018-052432

(51) Int. Cl. G01N 27/12; H01L 51/00

(52) U.S. Cl. CPC G01N 27/126; H01L 51/0037; H01L 51/0036

(57) ABSTRACT

A detection device includes, a first electrode, a second electrode, a conductor including at least a surface portion made of gold or platinum group metal, which extends from the first electrode to the second electrode so as to make an electric conduction between the first electrode and the second electrode, and a p-type semiconductor provided between the surface portion of the conductor and at least one of the first electrode and the second electrode so as to make an electric connection between the surface portion of the conductor and at least one of the first electrode and the second electrode.

### CROSS-REFERENCE TO RELATED APPLICATION

This application is based upon and claims the benefit of priority of the prior Japanese Patent Application No. 2018-052432, filed on Mar. 20, 2018, the entire contents of which are incorporated herein by reference.

### FIELD

The embodiments discussed herein are related to a detection device, a measurement apparatus, and a manufacturing method for a detection device.

### BACKGROUND

As for a detector or a measurement apparatus, for example, a gas sensor or an odor sensor has been known in the related art. Such a sensor includes, for example, a conductive polymer that connects a pair of electrodes, and is configured to detect and measure a detection target substance based on a change in resistance when the detection target substance adheres to the conductive polymer.

There has been also proposed a hydrogen sulfide sensor in which gold nanoparticles are attached to the surface of a polyaniline nanowire provided to connect a pair of electrodes.

Related techniques are disclosed in, for example, Japanese Laid-open Patent Publication Nos. 11-023508, 10-123082, 05-288703, and 2003-139775, and an article by M. D. Shirsat et al., entitled “Polyaniline nanowires-gold nanoparticles hybrid network based chemiresistive hydrogen sulfide sensor,” Appl. Phys. Lett., vol. 94, 083502 (2009) (non-Patent Document 1).

### SUMMARY

According to an aspect of the embodiments, a detection device includes, a first electrode, a second electrode, a conductor including at least a surface portion made of gold or platinum group metal, which extends from the first electrode to the second electrode so as to make an electric conduction between the first electrode and the second electrode, and a p-type semiconductor provided between the surface portion of the conductor and at least one of the first electrode and the second electrode so as to make an electric connection between the surface portion of the conductor and at least one of the first electrode and the second electrode.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a schematic sectional view illustrating the configuration of a gas sensor device provided in a detector according to an embodiment;

FIG. 2 is a schematic view illustrating the configuration of a detector and a measurement apparatus according to an embodiment;

FIGS. 3A and 3B are schematic views for explaining an operation mechanism in a detector according to an embodiment;

FIG. 4 is a view illustrating a response profile of a resistance value of a gas sensor device of Example 1 with respect to hydrogen sulfide having an atmospheric concentration of about 0.8 ppm;

FIG. 5 is a view illustrating a response profile of a resistance value of the gas sensor device of Example 1 with respect to ammonia having an atmospheric concentration of about 0.8 ppm;

FIG. 6 is a view illustrating a response profile of a resistance value of the gas sensor device of Example 1 with respect to nitrogen dioxide having an atmospheric concentration of about 0.5 ppm;

FIG. 7 is a view illustrating a response profile of a resistance value of the gas sensor device of Example 1 with respect to ethanol having an atmospheric concentration of about 18 ppm;

FIG. 8 is a graph illustrating a response profile of a resistance value of a gas sensor device of Example 2 when the gas sensor device is exposed to hydrogen sulfide having atmospheric concentrations of about 10 ppb, about 40 ppb, about 100 ppb, about 300 ppb, and about 600 ppb for about 60 seconds;

FIG. 9 is a graph in which a change in the response of the resistance value of the gas sensor device of Example 2 with respect to hydrogen sulfide having the atmospheric concentrations of about 10 ppb, about 40 ppb, about 100 ppb, about 300 ppb, and about 600 ppb for about 5 seconds after start of contact with hydrogen sulfide is plotted with respect to the concentrations of hydrogen sulfide and an approximate straight line is drawn;

FIG. 10 is a graph illustrating an intensity ratio (amplification factor) between a response of a gas sensor device not coated with P3HT with respect to hydrogen sulfide and response of a gas sensor device of Example 3 with respect to hydrogen sulfide, in which the horizontal axis represents the doping time; and

FIG. 11 is a graph illustrating a relative response intensity (selectivity) of gas sensor devices of Examples 1 and 4 to 7 and Comparative Example 1 with respect to a coating agent, a dopant, and various gases.

### DESCRIPTION OF EMBODIMENTS

In, for example, the above-described gas sensor or odor sensor of the related art, it is not clear whether or not the gas sensor or order sensor exhibits the selectivity to hydrogen sulfide.

In addition, with the above-described hydrogen sulfide sensor, it is difficult to selectively detect hydrogen sulfide.

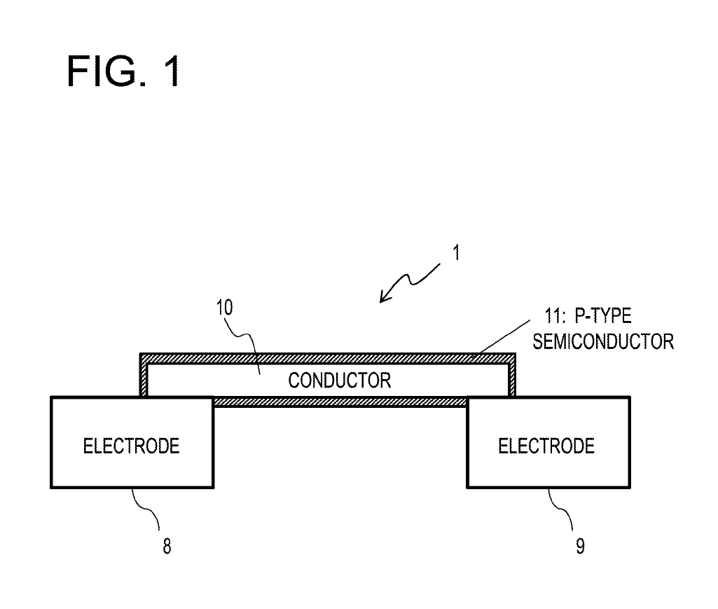

Hereinafter, a detector, a method of manufacturing the detector, and a measurement apparatus according to an embodiment of the present disclosure will be described with reference to FIGS. 1 to 11.

The detector according to the present embodiment is a device that detects chemical substances (detection target substances) in the atmosphere (gas), and particularly a detector capable of selectively detecting hydrogen sulfide as a detection target substance at a high speed and with high sensitivity.

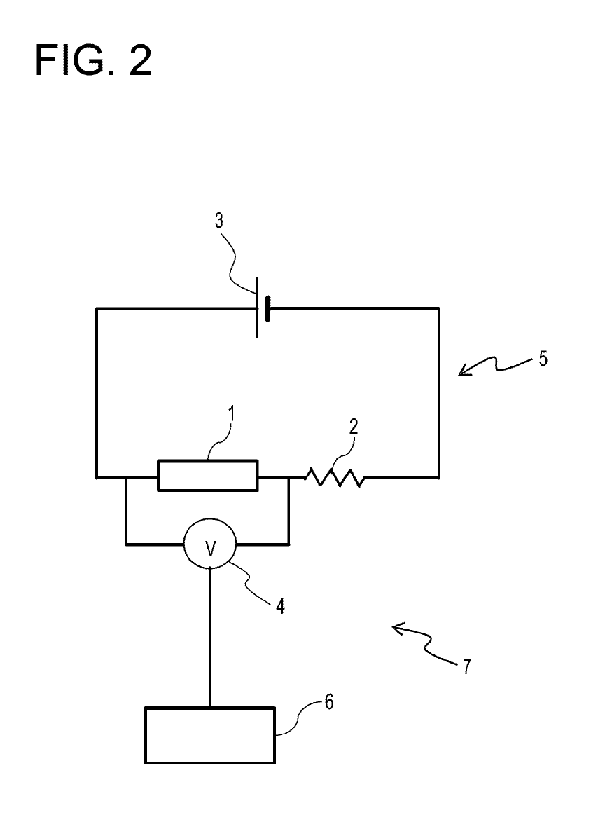

In the present embodiment, as illustrated in FIG. 2, a detector 5 includes a detection device 1, a fixed resistor 2 and a constant voltage power supply 3 that are connected to the detection device 1, and a potentiometer 4 that measures a potential difference between two electrodes provided in the detection device 1. A measurement apparatus 7 includes the above-described detector 5 and a converter 6.

The detector 5 is also referred to as a gas sensor or a sensor. The detection device 1 is also referred to as a gas sensor device or a sensor device.

Further, the detector 5 may be configured not to include the potentiometer 4 and the constant voltage power supply 3, and a potentiometer and a constant voltage power supply (external power supply) provided separately from the detector 5 may be connected to the detector 5.

In the present embodiment, the detector 5 configured as described above is connected to the converter 6 that converts a change in resistance detected by the detector 5 into a hydrogen sulfide concentration, thereby constituting the measurement apparatus 7.

That is, in the present embodiment, the measurement apparatus 7 includes the detector 5 configured as described above and the converter 6 that converts a change in resistance detected by the detector 5 into a hydrogen sulfide concentration. The measurement apparatus 7 is also referred to as a gas sensor system.

Here, the measurement apparatus 7 is configured to measure the concentration of hydrogen sulfide in the manner that the converter 6 converts the change in resistance (here, a resistance change rate) calculated based on a change in potential difference between two electrodes of the detection device 1, which is measured by the potentiometer 4 included in the detector 5 configured as described above, into the hydrogen sulfide concentration.

The resistance change rate is a ratio indicating how much the resistance value after exposure to a measurement target gas has changed relative to a resistance value before exposure to the measurement target gas.

Specifically, the hydrogen sulfide concentration is measured by converting the change in resistance value immediately after the contact with the measurement target gas (here, the resistance change rate) into the hydrogen sulfide concentration.

Here, the converter 6 is implemented by a computer including a processor such as a CPU. That is, a computer including a processor such as a CPU is connected to the detector 5 configured as described above, and this computer has the function of the converter 6.

In this case, the measurement apparatus 7 may be configured as a single measurement apparatus including the detector 5 configured as described above and the computer (the converter 6) including a processor such as a CPU, or may be configured by the detector 5 configured as described above and a separate computer (e.g., a personal computer or a server; the converter 6) connected thereto.

In particular, in the present embodiment, in order to selectively detect hydrogen sulfide, which is a toxic gas contained in, for example, volcanic gas and is also generated from the human body in association with, for example, alveolar pyorrhea or colitis, at a high speed and with high sensitivity, the detection device 1 is configured as follows.

Specifically, as illustrated in FIG. 1, the detection device 1 includes two electrodes 8 and 9, a conductor 10, and a p-type semiconductor 11. That is, the detector 5 of the present embodiment includes the two electrodes 8 and 9, the conductor 10, and the p-type semiconductor 11.

Here, the two electrodes 8 and 9 are a pair of electrodes.

Here, both of the two electrodes 8 and 9 are gold electrodes made entirely of gold.

The present disclosure is not limited thereto. The two electrodes 8 and 9 may be electrodes having at least their surfaces made of gold or platinum group metal.

For example, both of the two electrodes 8 and 9 may be electrodes in which their surface portions are made of gold and the other portions are made of another material such as platinum group metal. In addition, for example, both of the two electrodes 8 and 9 may be electrodes in which their surface portions are made of platinum group metal and the other portions are made of other materials. Further, for example, one of the two electrodes 8 and 9 may be an electrode entirely made of gold, and the other may be an electrode entirely made of platinum group metal.

The conductor 10 is a conductor entirely made of gold (e.g., a gold foil), which extends from one of the electrode 8 and 9 to the other so as to make electric conduction between the two electrodes 8 and 9. The two electrodes 8 and 9 are electrically connected by this conductor 10.

The present disclosure is not limited thereto. The conductor 10 may include at least a surface portion made of gold or platinum group metal, which extends from one of the electrode 8 and 9 to the other so as to make electric conduction between the two electrodes 8 and 9.

For example, the conductor 10 may be a conductor made entirely of platinum group metal, which extends from one of the electrode 8 and 9 to the other so as to make electric conduction between the two electrodes 8 and 9. In addition, for example, the conductor 10 may be a conductor in which its surface portion is made of gold, which extends from one of the electrode 8 and 9 to the other so as to make electric conduction between the two electrodes 8 and 9, and the other portion is made of other material. Further, for example, the conductor 10 may be a conductor in which its surface portion is made of platinum group metal, which extends from one of the electrode 8 and 9 to the other so as to make electric conduction between the two electrodes 8 and 9, and the other portion is made of other material.

The p-type semiconductor 11 is interposed between the conductor 10 and one of the two electrodes 8 and 9 so as to make electric connection therebetween, and is further interposed between the conductor 10 and the other of the two electrodes 8 and 9 so as to make electric connection therebetween. That is, the p-type semiconductor 11 is provided so as to bridge between the conductor 10 and one of the two electrodes 8 and 9 and between the conductor 10 and the other of the two electrodes 8 and 9.

The present disclosure is not limited thereto. The p-type semiconductor 11 may be interposed between the conductor 10 and at least one electrode 8 (9) so as to make (direct) electric connection therebetween. In addition, when the conductor 10 includes at least surface portion made of gold or platinum group metal, the p-type semiconductor 11 may be interposed between the surface portion of the conductor 10 and at least one electrode 8 (9) so as to make (direct) electric connection therebetween.

Here, the p-type semiconductor 11 is a p-type semiconductor film that covers the surface of the conductor 10. In this way, by covering the gold or platinum group metal surface portion of the conductor 10 with the p-type semiconductor 11, the selectivity to hydrogen sulfide may be further improved.

In this embodiment, the p-type semiconductor 11 covers the entire surface of the conductor 10 and is in contact with the conductor 10 and one of the two electrodes 8 and 9 and further in contact with the conductor 10 and the other of the two electrodes 8 and 9. The surface of the conductor 10 may be partially covered with the p-type semiconductor 11.

In the relation to the work function of gold or platinum group metal constituting at least the surface portion of the conductor 10, the p-type semiconductor 11 has a work function of electrons flowing from the surface portion in accordance with adhesion of hydrogen sulfide to the surface portion.

Here, the p-type semiconductor 11 is preferably polythiophene.

Specifically, preferably, the polythiophene is poly(3-alkylthiophene) or poly(3,4-ethylenedioxythiophene).

There are no restrictions on the type of polythiophene in principle, but poly(3-alkylthiophene) or poly(3,4-ethylenedioxythiophene) having high solvent solubility is advantageous because of its high manufacturability. In addition, since poly(3-alkylthiophene) is hydrophobic, it is advantageous in that it is hardly affected by humidity.

Further, it is preferable that polythiophene contains sulfuric acid or sulfonic acid (i.e., sulfonates including sulfonic acid) as a dopant. That is, polythiophene is preferably doped with sulfuric acid or sulfonic acid.

The doping effect on such polythiophene appears mainly in selectivity for gas species. The dopant which increases the carrier concentration of polythiophene is an oxidizing agent or an acid. In particular, by using sulfuric acid or sulfonic acid, which is a nonvolatile strong acid, at a rate at which the sulfuric acid or sulfonic acid functions as an acid even after donating proton to polythiophene, it is possible to effectively suppress the response to an acidic gas in the atmosphere including nitrogen dioxide.

Here, the p-type semiconductor 11 is polythiophene which is one of p-type organic semiconductors. However, the present disclosure is not limited thereto. For example, it may be other p-type organic semiconductor or a p-type inorganic semiconductor. However, in consideration of easy fabrication, the p-type semiconductor 11 is preferably a p-type organic semiconductor.

A connection region between one of the two electrodes 8 and 9 and the conductor 10 and the p-type semiconductor 11 and a connection region between the other of the two electrodes 8 and 9 and the conductor 10 and the p-type semiconductor 11 are exposed to the atmosphere.

That is, the connection region between one of the two electrodes 8 and 9 and the conductor 10 and the p-type semiconductor 11 and the connection region between the other of the two electrodes 8 and 9 and the conductor 10 and the p-type semiconductor 11 are exposed to the atmosphere including the detection target substance (here, hydrogen sulfide; the measurement target gas).

The present disclosure is not limited thereto. A connection region between at least one electrode 8 (9) and the surface portion of the conductor 10 and the p-type semiconductor 11 may be exposed to the atmosphere. That is, the connection region between at least one electrode 8 (9) and the surface portion of the conductor 10 and the p-type semiconductor 11 may be exposed to the atmosphere containing the detection target substance (here, hydrogen sulfide; the measurement target gas). In addition, a region where the conductor 10 is in contact with the electrodes 8 and 9 (a contact point between the conductor 10 and the electrodes 8 and 9) and a region where the p-type semiconductor 11 is in contact with the conductor 10 and both of the electrodes 8 and 9 (a contact point between the p-type semiconductor 11 and the conductor 10 and the electrodes 8 and 9) may be exposed to the atmosphere.

Further, the detector 5 configured as described above may be manufactured as follows.

Specifically, a method of manufacturing the detector according to the present embodiment may include a step of providing two electrodes 8 and 9, a step of providing a conductor 10 including a surface portion made of gold or platinum group metal, which extends from one of the two electrodes 8, 9 to the other so as to make electric conduction therebetween, and a step of providing a p-type semiconductor 11 between the surface portion of the substrate 10 and at least one electrode 8 (9) so as to make electric conduction therebetween.

The reason for the above configuration is as follows.

A current mainstream gas sensor is configured to measure a change in electric resistance caused by adsorption of a chemical substance on the surface of a semiconductor typified by tin dioxide.

With such a configuration, in order to measure a gas with high sensitivity, it is necessary to supply a current using a constant current power supply and heat a device to a temperature region where good detection characteristics (sense characteristics) is obtained.

For this reason, the power consumption of a detection circuit itself tends to increase, and much power is consumed by a heater for heating the device.

This type of gas sensor exhibits a similar response to many kinds of reducible gases contacting the sensor device.

For this reason, it is difficult to know a type of gas to which the response of the sensor device is related.

Meanwhile, there is also a detection material (sense material) which may constitute a resistance variable gas sensor device at the room temperature and exhibits a selective response to a specific gas type. A p-type semiconductor which is one type of copper halide, for example, cuprous bromide (CuBr), is a representative example of the detection material. There is a device which uses CuBr as a detection material and exhibits a large electric resistance change selectively at the room temperature with respect to ammonia in the atmosphere.

Although not common at present, there is also a device that uses an organic semiconductor as a detection material. For example, the above-mentioned Japanese Laid-open Patent Publication No. 11-023508 discloses an example where polythiophene, which is an organic semiconductor, is used as a detection material, and an example where polythiophene doped with ferric chloride is used as a detection material. However, Japanese Laid-open Patent Publication No. 11-023508 does not clearly disclose whether or not the disclosed sensor device exhibits the selectivity to specific gas types.

As described above, the detection material for the gas sensor device that selectively responds to ammonia with high sensitivity may be, for example, CuBr.

However, there is no known detection material for a gas sensor which exhibits high selectivity to hydrogen sulfide as described above and is capable of measuring hydrogen sulfide at a high speed, for example, within one minute.

Further, with the hydrogen sulfide sensor described in the above-mentioned non-Patent Document 1, it is difficult to selectively detect only hydrogen sulfide.

Therefore, in order to selectively detect hydrogen sulfide, which is a toxic gas contained in, for example, a volcanic gas and is generated from the human body in association with, for example, alveolar pyorrhea or colitis, at a high speed and with high sensitivity, the above-described configuration is adopted.

Here, the hydrogen sulfide has the ability to form a coordination bond to various metal atoms or metal ions.

However, since other gas species also have the ability to form a coordination bond to various metal atoms or metal ions, the coordination bond formation is usually competitive among these gas species.

Therefore, by using a material that is inert to most types of gases and has the ability to form a reversible bond to hydrogen sulfide, it becomes possible to fabricate a device a sensor selectively reacting to hydrogen sulfide.

An example of such a material is gold. For example, the above-mentioned non-Patent Document 1 discloses a device for detecting hydrogen sulfide using a change in resistance of polyaniline which is an organic semiconductor and connects between a pair of electrodes, and strengthening a response to hydrogen sulfide by attaching nano-particles to the surface of polyaniline.

Meanwhile, in a case where a gas sensor that performs measurement using a resistance change of a semiconductor material without being limited to the organic semiconductor, in general, since the gas sensor exhibits some response to polar gas components, it is inevitable that a response to a vast of water molecules, which are polar molecules existing in air, that is, a response to humidity, occurs. Thus, in the present embodiment, as described above, the conductor 10 having at least a surface made of gold is connected between the pair of electrodes 8 and 9 (see, e.g., FIG. 1).

However, merely by making electric conduction between the pair of electrodes 8 and 9 by such a conductor 10, the change in resistance is slight and it is difficult to put it into practical use as a gas sensor device.

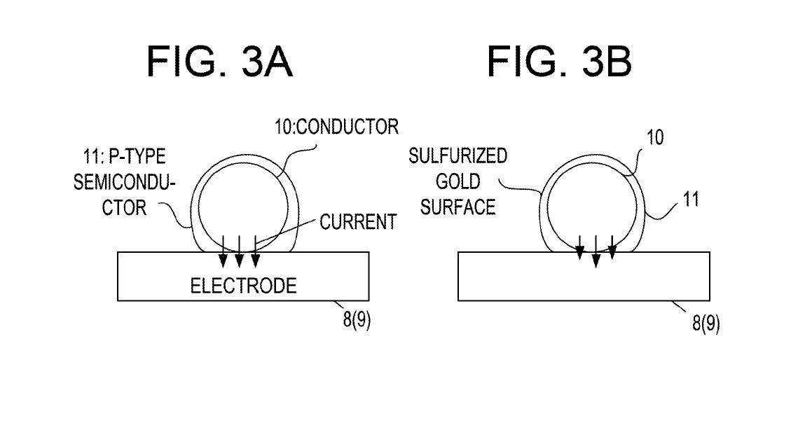

For this reason, a semiconductor (here, the p-type semiconductor 11) having a work function close to that of gold constituting the conductor 10 is brought into contact with the pair of electrodes 8 and 9 and the gold constituting at least the surface of the conductor 10 connecting between the pair of electrodes 8 and 9 so that the conductor-semiconductor-electrode connection is in parallel to the conductor-electrode connection (see, e.g., FIGS. 1, 3A, and 3B).

Hydrogen sulfide makes reversible bond with gold at the room temperature. The sulfurization of the gold surface results in decrease in the work function of the gold surface.

In a case of using a thin film of an organic semiconductor (organic semiconductor film) as the semiconductor, even when the entire surface of the conductor 10 is covered with the organic semiconductor film, the gas component in the atmosphere may penetrate to the surface of gold. Therefore, as the hydrogen sulfide that has passed through the organic semiconductor film sulfurizes the surface of gold, the surface of gold in contact with the organic semiconductor film is sulfurized and the work function of the surface is reduced.

Therefore, when the work function of the semiconductor is close to the work function of gold, electrons are introduced from the gold into the semiconductor, accompanied by the sulfurization of the surface of gold.

When the p-type semiconductor 11 is used as the semiconductor, for example, as illustrated in FIGS. 3A and 3B, as the surface of gold constituting the conductor 10 is sulfurized by hydrogen sulfide, electrons are introduced into the p-type semiconductor 11, and the concentration of holes serving as carriers decreases, which results in a change in resistance of the gas sensor device 1 in a way in which the resistance of the gas sensor device 1 increases.

In this way, it is possible to implement a practical gas sensor device 1 in which resistance is sufficiently changed as a response to hydrogen sulfide.

In addition, as apparent from the above-described operation mechanism, the gas sensor device 1 functions well even when at least the surface of the conductor 10 connecting between the pair of electrodes 8 and 9 is made of gold. However, the effect of the gas sensor device 1 is maximized when all the surfaces of the conductor 10 connecting between the pair of electrodes 8 and 9 are made of gold.

In addition, since the reaction of hydrogen sulfide with respect to the surface of gold is a primary reaction in which a reaction rate is proportional to the concentration of hydrogen sulfide, a slope (change in resistance; temporal change of resistance change rate) at the rising of the response from the initial state of the gas sensor device 1 is proportional to the concentration of hydrogen sulfide in the atmosphere. Therefore, it is possible to calculate the concentration of hydrogen sulfide in the atmosphere from the initial response of the gas sensor device 1 to a measurement target gas (observation target gas).

In particular, the reaction of hydrogen sulfide with respect to the surface of gold is speedy at the room temperature, and by using the initial response, it becomes possible to measure the concentration of hydrogen sulfide within, for example, about 10 seconds.

In addition, in the clean atmosphere, since the reverse reaction of hydrogen sulfide separating from the sulfurized surface of gold occurs spontaneously on the surface of gold, it is possible to initialize the device without performing an operation such as heating or light irradiation.

Although the case of using gold has been described, a case of using platinum group metal (noble metal except for silver) may obtain the same effects.

Therefore, the detector, the method of manufacturing the same, and the measurement apparatus according to the present embodiment have the effects of selective detection of hydrogen sulfide.

In particular, it is possible to implement a detector and a measurement apparatus that selectively respond to hydrogen sulfide, and thus, are able to perform detection and measurement at a high speed and with high sensitivity.

### EXAMPLES

Hereinafter, the present disclosure will be described in more detail by way of Examples. However, the present disclosure is not limited by the following Examples.

### Example 1

In Example 1, a gold foil (conductor) 10 having a width of about 2 μm was passed between a pair of gold electrodes 8 and 9 formed at intervals of about 5 μm on a glass substrate having a width of about 6 mm and a length of about 25 mm, and then its conductivity was checked. Thereafter, an approximately 1 μL of an orthodichlorobenzene solution having a concentration of about 0.11% by weight of poly(3-hexylthiophene) (P3HT) which is the p-type semiconductor 11 was dropped on the gold foil 10 and, after about 10 seconds, the excess solution was removed by tilting the substrate vertically.

In this way, the gold foil (conductor) 10 was provided so as to make electrical conduction between the pair of gold electrodes 8 and 9, and the surface of this gold foil is covered (coated) with P3HT (p-type semiconductor 11; p-type organic semiconductor; polythiophene; poly(3-alkyl thiophene)) 11 (see, e.g., FIG. 1).

After air drying, about 50 μL of a methanol solution of sulfuric acid having a concentration of about 0.01% by volume was dropped and doping treatment was carried out for about 60 seconds. Thereafter, the surface of the gold foil was washed with pure methanol and was air-dried.

In this way, P3HT was assumed to contain sulfuric acid as a dopant. Thereafter, annealing was performed at about 150° C. for about 10 minutes in the atmosphere to fabricate a gas sensor device 1 (see, e.g., FIG. 1).

Then, the fabricated gas sensor device 1 was set in an air flow, a gas source was switched between the clean air and one of hydrogen sulfide having a concentration of about 0.8 ppm, ammonia having a concentration of about 0.8 ppm, nitrogen dioxide having a concentration of about 0.5 ppm, and air containing ethanol having a concentration of about 18 ppm, and the responses of the gas sensor device 1 fabricated as described above to these gases were evaluated.

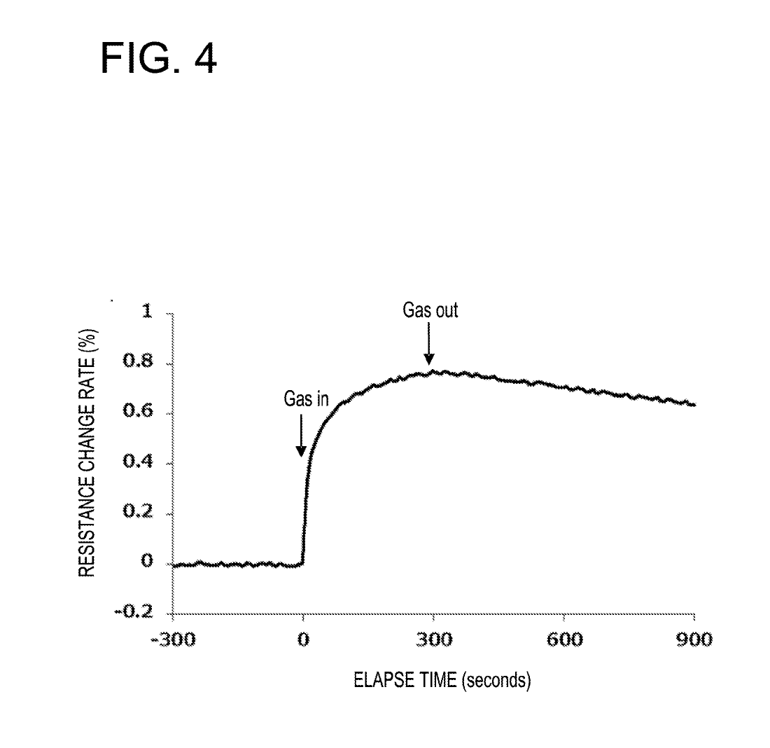

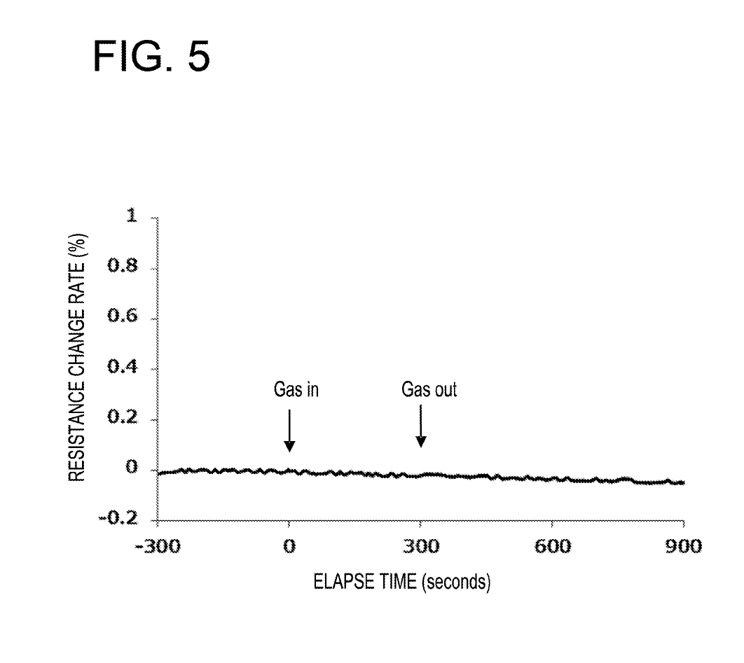

The temperature of the air used here was about 24° C. and the relative humidity was about 40%. FIG. 4 is a graph illustrating a response of the electric resistance (resistance value) of the gas sensor device 1 fabricated as described above with respect to hydrogen sulfide (here, a profile of response of the resistance change rate to hydrogen sulfide having an atmospheric concentration of about 0.8 ppm). FIG. 5 is a graph illustrating a response of the electric resistance (resistance value) of the gas sensor device 1 fabricated as described above with respect to ammonia (here, a profile of response of the resistance change rate to ammonia having an atmospheric concentration of about 0.8 ppm).

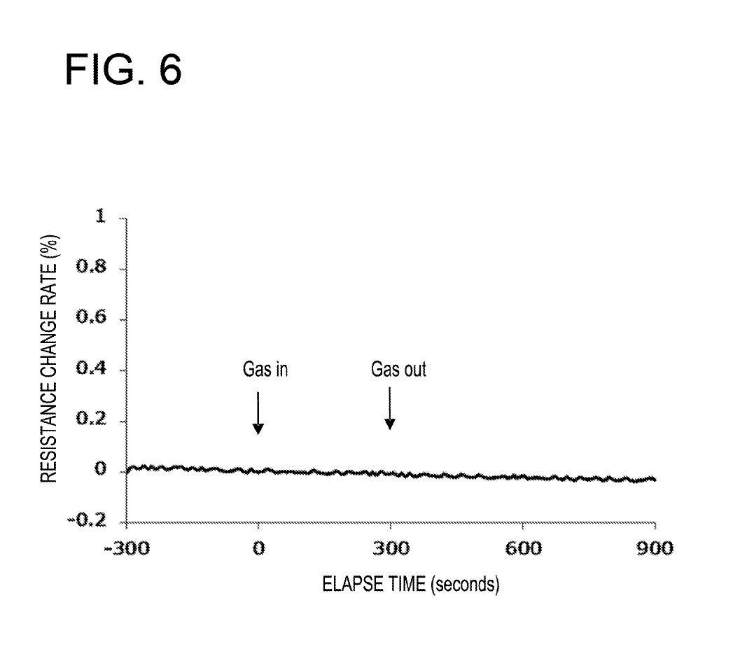

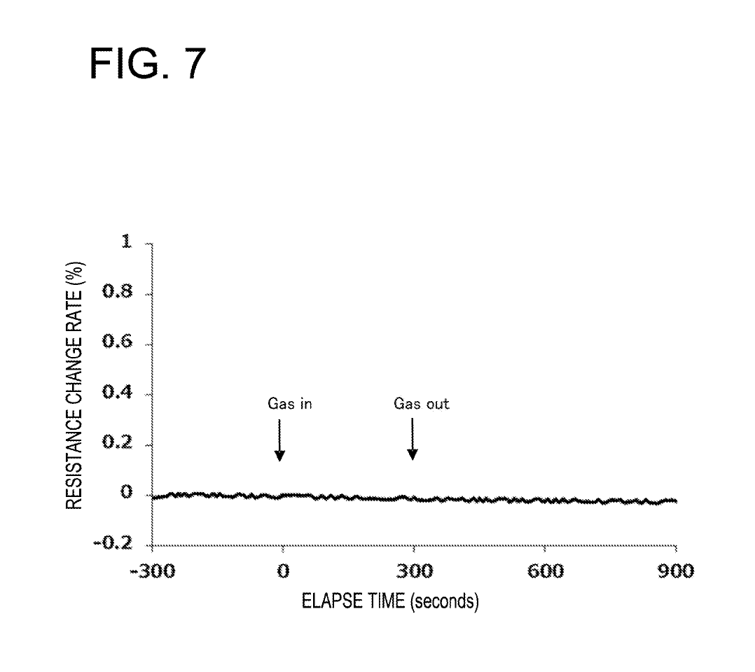

FIG. 6 is a graph illustrating a response of the electric resistance (resistance value) of the gas sensor device 1 fabricated as described above with respect to nitrogen dioxide (here, a profile of response of the resistance change rate to nitrogen dioxide having an atmospheric concentration of about 0.5 ppm). FIG. 7 is a graph illustrating a response of the electric resistance (resistance value) of the gas sensor device 1 fabricated as described above with respect to ethanol (here, a profile of response of the resistance change rate to ethanol having an atmospheric concentration of about 18 ppm).

The resistance change rate is a ratio of resistance after exposure to each gas to resistance before exposure to each gas.

As illustrated in FIGS. 4 to 7, the selectivity of gas species to hydrogen sulfide is extremely high.

The resistance value of the gas sensor device 1 fabricated as described above did not exhibit any significant change for a variation from about 20% to about 65% of the relative humidity in the clean air.

In this way, according to the gas sensor device 1 fabricated as described above, it was confirmed that the gas sensor device 1 selectively responds to hydrogen sulfide, which is a detection target substance, can detect hydrogen sulfide with high sensitivity, and is less susceptible to the influence of a change in humidity.

### Example 2

In Example 2, a gas sensor device 1 was fabricated in the same manner as Example 1, and a response of the gas sensor device 1 was evaluated when the gas sensor device 1 is contacted with hydrogen sulfide of a changed concentration for about 60 seconds.

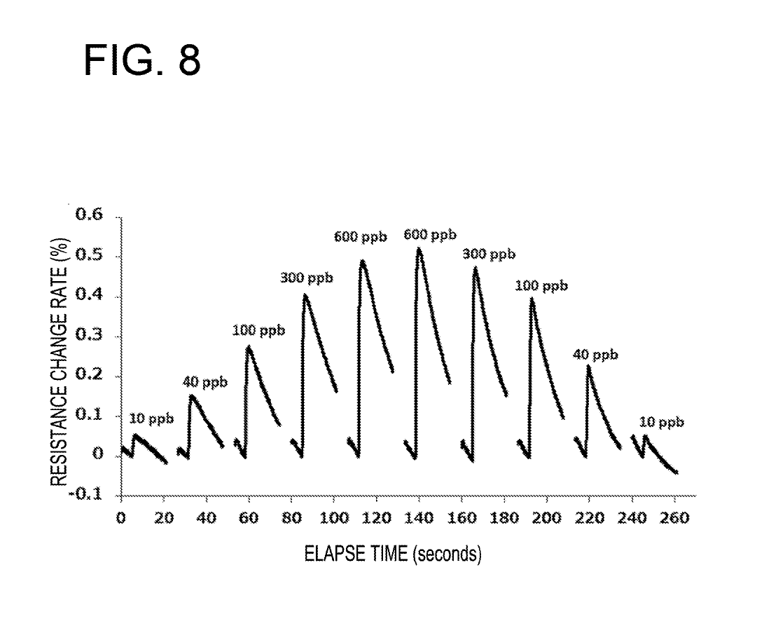

FIG. 8 is a graph illustrating a response of the resistance value of the gas sensor device 1 of Example 2 (a profile of response of the resistance change rate) when the gas sensor device 1 is exposed to hydrogen sulfide having atmospheric concentrations of about 10 ppb, about 40 ppb, about 100 ppb, about 300 ppb, and about 600 ppb for about 60 seconds.

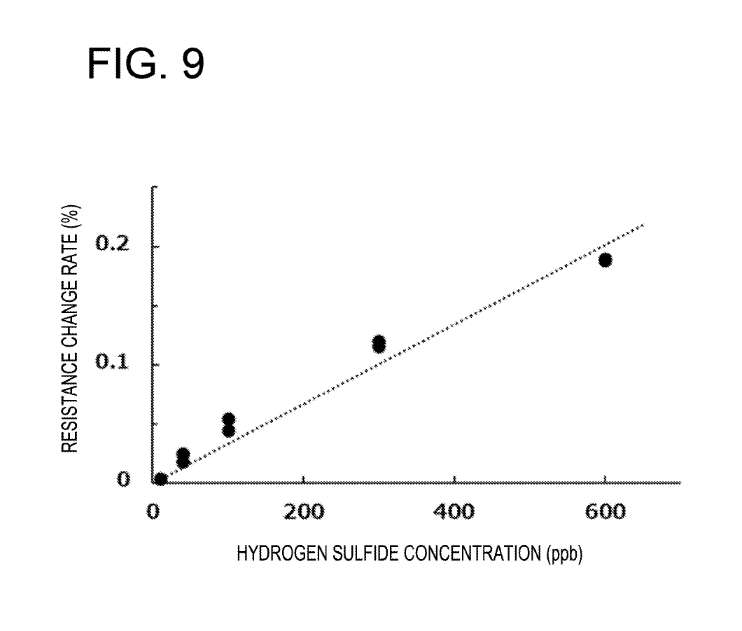

FIG. 9 is a graph in which a change in resistance change rate for the first about 5 seconds in each response section illustrated in FIG. 8 is plotted with respect to the concentrations of hydrogen sulfide used and an approximate straight line (see a dotted line in the figure) is drawn.

That is, FIG. 9 is a graph in which a change in the response of the resistance value of the gas sensor device 1 of Example 2 (a profile of response of the resistance change rate) with respect to hydrogen sulfide having atmospheric concentrations of about 10 ppb, about 40 ppb, about 100 ppb, about 300 ppb, and about 600 ppb for about 5 seconds after start of contact with hydrogen sulfide is plotted with respect to the concentrations of hydrogen sulfide and an approximate straight line (see a dotted line in the figure) is drawn.

The results illustrated in FIGS. 8 and 9 illustrate that the response intensity of the gas sensor device 1 of Example 2 has excellent linearity with respect to the concentration of hydrogen sulfide, particularly in the initial response region of about 5 seconds from start of exposure, and the gas sensor device 1 of Example 2 is a highly sensitive gas sensor device having both quantitativity and high speed.

### Example 3

In Example 3, a gas sensor device 1 was fabricated in the same manner as Example 1 described above. In this case, plural gas sensor devices 1 with different doping levels by changing the doping time were fabricated.

In addition, using the same material and method as Example 1, gas sensor devices in each of which a pair of gold electrodes 8 and 9 was electrically connected only by a gold foil 10, that is, gas sensor devices not coated with P3HT, were prepared.

Then, for these gas sensor devices, the response to air containing hydrogen sulfide of a concentration of about 0.8 ppm was measured and the ratio of the response intensity for the gas sensor devices not coated with P3HT (amplification factor: a value at about 60 seconds after start of exposure to hydrogen sulfide) was obtained.

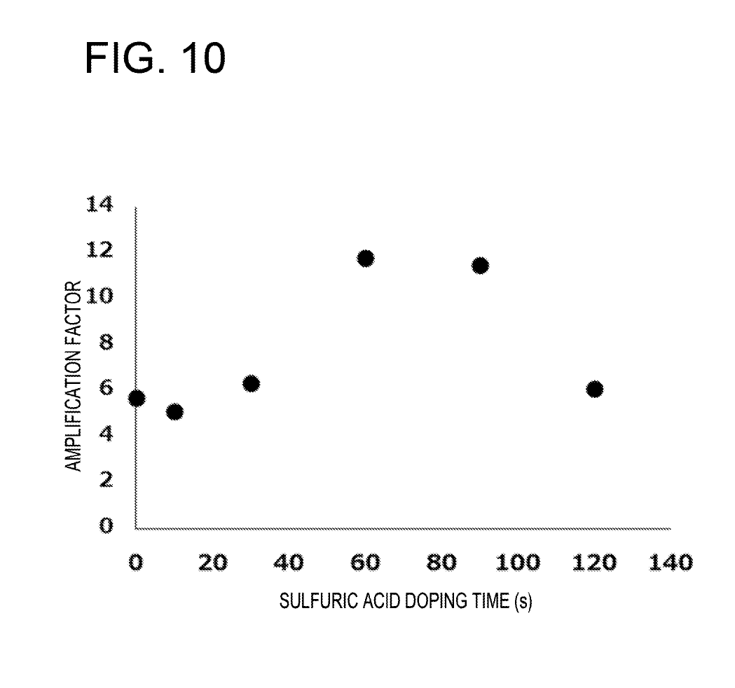

FIG. 10 illustrates the results. That is, FIG. 10 is a graph illustrating the intensity ratio (amplification factor) of the response to hydrogen sulfide of the gas sensor devices not coated with P3HT and the response to hydrogen sulfide of the gas sensor device 1 of Example 3, in which the horizontal axis represents the doping time.

As illustrated in FIG. 10, as in the gas sensor device 1 of Example 3, by coating with P3HT, the response to hydrogen sulfide increases by about 5 times, particularly about 10 times or more when the doping by sulfuric acid is in a suitable range.

### Examples 4 to 7 and Comparative Example 1

In Examples 4 to 7, gas sensor devices were fabricated while changing coating agents and dopants made of a p-type semiconductor, in the same manner as Example 1.

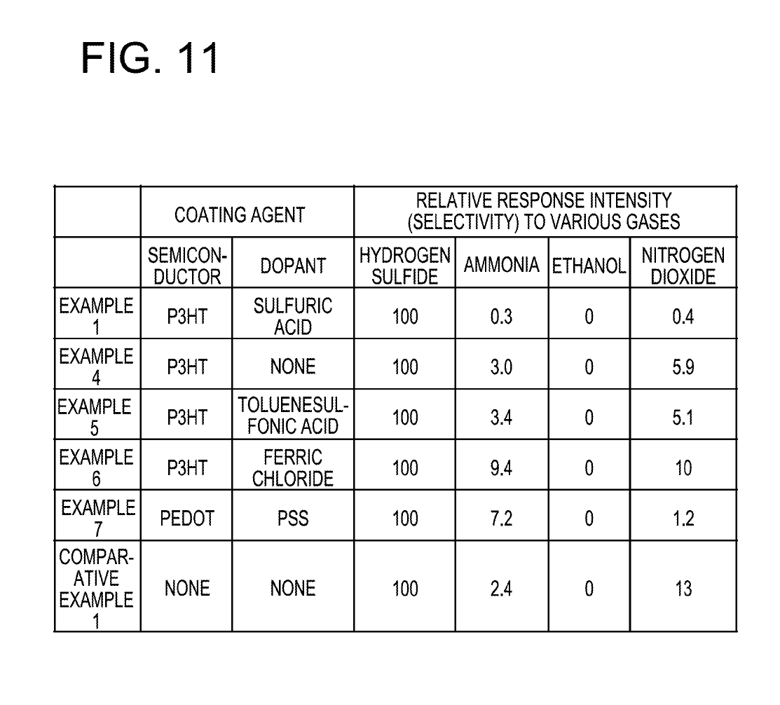

That is, as illustrated in FIG. 11, in Example 4, a gas sensor device was fabricated with P3HT as a coating agent but no dopant was used. In Example 5, a gas sensor device was fabricated with P3HT as a coating agent and toluenesulfonic acid as a dopant. In Example 6, a gas sensor device was fabricated with P3HT as a coating agent and ferric chloride as a dopant. In Example 7, a gas sensor device was fabricated with poly(3,4-ethylenedioxythiophene) (PEDOT) as a coating agent and polystyrene sulfonic acid (PSS) as a dopant.

As Comparative Example, gas sensor devices were fabricated with neither doping nor coating, in the same manner as Example 1.

Then, the responses of these gas sensor devices to hydrogen sulfide, ammonia, ethanol and nitrogen dioxide were measured and the response ratio of these gas sensor devices of nitrogen dioxide, ammonia and ethanol to hydrogen sulfide was normalized using the concentrations of the used gases to obtain the relative response intensity (selectivity) for the various gases. The results are illustrated in FIG. 11 together with the results of the gas sensor device of Example 1.

As illustrated in FIG. 11, by coating as in Examples 1 and 4 to 7, the selectivity to hydrogen sulfide was improved over Comparative Example 1 in which no coating was performed. In particular, in Examples 1, 4, 5, and 7 in which the gas sensor devices were coated with P3HT or PEDOT, except for Example 6 in which the dopant was ferric chloride, which is an oxidizing agent which is not an acid, the response to nitrogen dioxide could be suppressed to some extents, considerably improving the selectivity to hydrogen sulfide over Comparative Example 1 in which no coating was performed.

In addition, as compared with Example 4 where no dopant was used, in Examples 1, 5, and 7 in which sulfuric acid or sulfonic acid was doped, the response to nitrogen dioxide was declined and the selectivity to hydrogen sulfide was improved. In particular, in Example 1 in which sulfuric acid was doped, the response to nitrogen dioxide was considerably declined and the selectivity to hydrogen sulfide was considerably improved.

In addition, in Examples 1 and 4 to 6, no significant resistance change was observed when the relative humidity in clean air was increased from about 20% to about 65%.

Meanwhile, in Example 7 using PEDOT which is hydrophilic polythiophene, a resistance change corresponding to about 55% of the response to hydrogen sulfide of a concentration of about 0.8 ppm was exhibited according to the same humidity change, i.e., it was sensitive to the humidity change. In this way, by using P3HT, it was confirmed that a gas sensor device is less susceptible to the influence of the humidity change.

All examples and conditional language recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority and inferiority of the disclosure. Although the embodiment(s) of the present disclosure has (have) been described in detail, it should be understood that the various changes, substitutions, and alterations could be made hereto without departing from the spirit and scope of the disclosure.

What is claimed is:

1. A detection device comprising:
a first electrode and a second electrode;
a conductor including at least a surface portion made of gold or platinum group metal, which extends from the first electrode to the second electrode so as to make an electric conduction between the first electrode and the second electrode; and
a p-type semiconductor provided between the surface portion of the conductor and at least one of the first electrode and the second electrode so as to make an electric connection between the surface portion of the conductor and at least one of the first electrode and the second electrode.

2. The detection device according to claim 1,
wherein the p-type semiconductor is polythiophene.

3. The detection device according to claim 2,
wherein the polythiophene is poly(3-alkylthiophene) or poly(3,4-ethylenedioxythiophene).

4. The detection device according to claim 2,
wherein the polythiophene contains sulfuric acid or sulfonic acid as a dopant.

5. The detection device according to claim 1,
wherein the p-type semiconductor is a p-type organic semiconductor.

6. The detection device according to claim 1,
wherein the p-type semiconductor has a work function of electrons flowing from the surface portion in accordance with adhesion of hydrogen sulfide to the surface portion in relation to the work function of gold or platinum group metal constituting the surface portion.

7. The detection device according to claim 1,
wherein the p-type semiconductor is a p-type semiconductor film that covers the surface of the conductor.

8. The detection device according to claim 1,
wherein at least the surface of the first electrode and the second electrode are made of gold or platinum group metal.

9. The detection device according to claim 1,
wherein at least one of the first electrode and the second electrode, the surface portion of the conductor, and a connection region of the p-type semiconductor are exposed to the atmosphere.

10. A measurement apparatus comprising:
a detection device including:
a first electrode and a second electrode,
a conductor including at least a surface portion made of gold or platinum group metal, which extends from the first electrode to the second electrode so as to make an electric conduction between the first electrode and the second electrode, and
a p-type semiconductor provided between the surface portion of the conductor and at least one of the first electrode and the second electrode so as to make an electric connection between the surface portion of the conductor and at least one of the first electrode and the second electrode;
a resistor connected in series with the detection device;
a power supply configured to supply a DC voltage to the detection device and the resistor;
a potentiometer configured to measure a potential difference between the first electrode and the second electrode of the detection device; and
a converter configured to convert a resistance change calculated based on a change in a potential difference at a predetermined time into a hydrogen sulfide concentration.

11. The measurement apparatus according to claim 10,
wherein the p-type semiconductor is polythiophene.

12. The measurement apparatus according to claim 11,
wherein the polythiophene is poly(3-alkylthiophene) or poly(3,4-ethylenedioxythiophene).

13. The measurement apparatus according to claim 11,
wherein the polythiophene contains sulfuric acid or sulfonic acid as a dopant.

14. The measurement apparatus according to claim 10,
wherein the p-type semiconductor is a p-type organic semiconductor.

15. The measurement apparatus according to claim 10,
wherein the p-type semiconductor has a work function of electrons flowing from the surface portion in accordance with adhesion of hydrogen sulfide to the surface portion in relation to the work function of gold or platinum group metal constituting the surface portion.

16. The measurement apparatus according to claim 10,
wherein the p-type semiconductor is a p-type semiconductor film that covers the surface of the conductor.

17. The measurement apparatus according to claim 10,
wherein at least the surface of the first electrode and the second electrode are made of gold or platinum group metal.

18. The measurement apparatus according to claim 10,
wherein at least one of the first electrode and the second electrode, the surface portion of the conductor and a connection region of the p-type semiconductor are exposed to the atmosphere.

19. A manufacturing method for a detection device, the method comprising:
forming a first electrode and a second electrode;
forming a conductor including at least a surface portion made of gold or platinum group metal, which extends from the first electrode to the second electrode so as to make an electric conduction between the first electrode and the second electrode; and
forming a p-type semiconductor between the surface portion of the conductor and at least one of the first electrode and the second electrode so as to make an electric connection between the surface portion of the conductor and the at least one of the first electrode and the second electrode.
